(19) United States
(12) Patent Application Publication
(10) Pub. No.: US 2005/0057123 A1
(43) Pub. Date: Mar. 17, 2005

(54) Piezoelectric vibration energy harvesting device and method

(76) Inventor: Ken Kan Deng, Potomac, MD (US)

Correspondence Address: BLANK ROME LLP, 600 NEW HAMPSHIRE AVENUE, N.W., WASHINGTON, DC, 20037, US

(21) Appl. No.: 10/887,216

(22) Filed: Jul. 9, 2004

Related U.S. Application Data
(60) Provisional application No. 60/486,172, filed on Jul. 11, 2003.

(51) Int. Cl. H01L 41/08

(52) U.S. Cl. 310/339

(57) ABSTRACT

A piezoelectric vibration energy harvesting device which is made up of a base, a proof mass, and a cymbal stack disposed between the base and the proof mass. The cymbal stack has a piezoelectric element disposed between the base and the proof mass, a first cymbal-shaped cap disposed between the proof mass and the piezoelectric crystal, and a second cymbal-shaped cap disposed between the piezoelectric crystal and the base.

### STATEMENT OF GOVERNMENT INTEREST

The work leading to the present invention was supported in party by Naval Surface Warfare Center Dahlgren Division (NSWCDD) Contract Number: N00178-03-C-3056. The government has certain rights in the invention.

### FIELD OF THE INVENTION

The present invention is directed to a highly efficient, small size, vibration harvesting and electric energy storage device. The energy level is high enough to power a wireless sensor.

### DESCRIPTION OF RELATED ART

Current technology utilizes a flexural, piezoelectric composite bending structure as a vibration energy to electric energy transducer. The selected piezoelectric materials are PZT ceramics or PVDF polymer. The output of this device is connected to an AC-DC converter which is typically composed of a diode rectifier with a storage capacitor.

The flexural mode piezoelectric effect (d₃₁ mode) is very inefficient; this results in a low conversion efficiency from vibration energy to electric energy (less than 10%). Besides, a flexural mode piezoelectric structure is bulky and not suitable for high frequency vibration condition. These drawbacks make the device impractical for application.

### SUMMARY OF THE INVENTION

It is therefore an object of the invention to efficiently harvest vibration kinetic energy from the ambient environment or machinery and store it in the form of electric energy, which later is used to power an electronic device. A highly efficient, small size vibration harvesting device will enable a self-powered, truly wireless transducer system.

By using the state-of-the-art relaxor single crystal, which exhibits the highest piezoelectric coupling coefficient, and a compression-tension, piezoelectric composite, cymbal structure, a compact, highly efficient vibration energy extracting device is accomplished. Moreover, before connecting the stack with a rectifier/storage circuit, an inductor L is introduced which is parallel with the piezoelectric stack. The resonance of the LC loop is tuned around the resonance of the stack. This inductor will greatly improve the electric energy transferring efficiency.

The major difference between the prior art and this design is in the piezoelectric transduction structure. Instead of using a flexural plate or beam, the new vibration energy harvesting device uses a composite cymbal stack with a proof mass on top. During vibration, the inertial force is transmitted to the piezoelectric disk through the circular cymbal caps. Then the piezoelectric disk is under both compression and tension stresses (d₃₃+d₃₁ mode). The present invention is therefore more efficient than the prior art where the piezoelectric layer is only subject to in-plane stress (d₃₁ mode). Another major change is the transduction material; a relaxor crystal, which has the highest piezoelectric property, is incorporated in the device. In addition, the electric output from the cymbal stack is connected to an inductor before it is linked to a rectifier. The resonance frequency of the inductor L and piezoelectric crystal Cₓ is tuned to be approximately the same as the mechanical resonance of the cymbal stack. Doing so, the electric energy flows much efficiently from the harvesting device to the storage capacitor.

The invention allows for a much more efficient vibration energy harvesting device. It also allows a very small size.

### BRIEF DESCRIPTION OF THE DRAWINGS

FIG. 1 shows a diagram of the device with the cymbal stack.

FIGS. 2 and 3 show circuit diagrams of the device of FIG. 1 connected to different rectifiers.

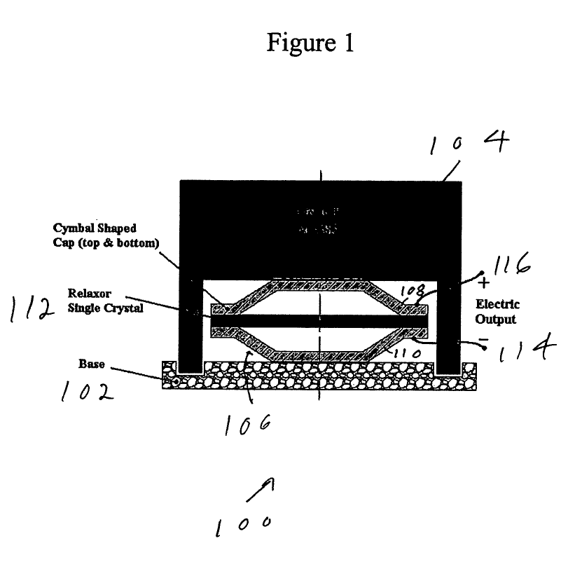

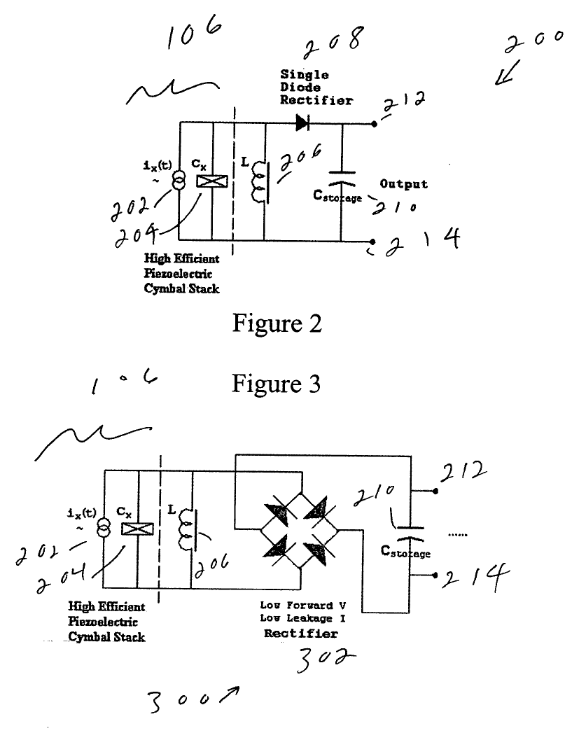

In FIGS. 2 and 3, the device of FIG. 1 is represented by an equivalent circuit to the left of the dashed line.

### DETAILED DESCRIPTION OF THE PREFERRED EMBODIMENT

A preferred embodiment of the present invention will now be set forth in detail, including two circuits incorporating it.

FIG. 1 shows an energy harvesting device 100. The device includes a base 102 and a proof mass 104. Disposed between the base 102 and the proof mass 104 is a cymbal stack 106 including top and bottom cymbal-shaped caps 108, 110 sandwiching a relaxor single crystal 112. The cymbal-shaped caps are connected to electrodes 114, 116 forming an electric output.

FIG. 2 shows a first circuit 200 incorporating the energy harvesting device 100. In the circuit diagram of FIG. 2, the cymbal stack 106 is represented by an equivalent circuit comprising a current source 202 and a capacitor 204. Connected in parallel across the output of the cymbal stack is an inductor 206. A single diode rectifier 208, a storage capacitor 210 and output electrodes 212, 214 complete the circuit 200.

FIG. 3 shows a second circuit 300 incorporating the energy harvesting device 100. The single diode rectifier 208 is replaced with a low forward voltage, low leakage current rectifier 302.

While a preferred embodiment of the present invention has been set forth above, those skilled in the art will recognize that other embodiments can be realized within the scope of the invention, which should therefore be construed as limited only by the claims to be set forth in the non-provisional application.

1. A piezoelectric vibration energy harvesting device comprising:
a base;
a proof mass; and
a cymbal stack disposed between the base and the proof mass, the cymbal stack comprising:
a piezoelectric element disposed between the base and the proof mass;
a first cymbal-shaped cap disposed between the proof mass and the piezoelectric crystal; and
a second cymbal-shaped cap disposed between the piezoelectric crystal and the base.

2. The device of claim 1, wherein the piezoelectric element is a relaxor crystal.

3. The device of claim 1, wherein the first and second cymbal-shaped caps also function as electrodes and are connected to an electric output of the device.

4. The device of claim 1, wherein the electrical output is connected to an inductor.

5. The device of claim 4, wherein the piezoelectric element and the inductor have a resonance frequency which is tuned to be approximately equal to a mechanical resonance of the cymbal stack.
